(19) United States
(12) Patent Application Publication
(10) Pub. No.: US 2026/0047331 A1
(43) Pub. Date: Feb. 12, 2026

(54) METHOD OF MANUFACTURING DISPLAY APPARATUS

(71) Applicant: Samsung Display Co., Ltd., Yongin-si (KR)

(72) Inventor: Jaehoon Kim, Yongin-si (KR)

(73) Assignee: Samsung Display Co., Ltd., Yongin-si (KR)

(21) Appl. No.: 19/174,469

(22) Filed: Apr. 9, 2025

(30) Foreign Application Priority Data
Aug. 9, 2024 (KR) 10-2024-0107085

(51) Int. Cl. H10K 71/40; H10K 59/12; H10K 59/122; H10K 59/80

(52) U.S. Cl. CPC H10K 71/40; H10K 59/1201; H10K 59/122; H10K 59/879

(57) ABSTRACT

Provided is a method of manufacturing a display apparatus, the method including providing a substrate on which a display element is disposed, forming a bank layer on the substrate, the bank layer including an opening overlapping the display element, forming a preliminary high refractive lens by coating the display element with a material for forming a high refractive lens and irradiating the material for forming the high refractive lens with ultraviolet rays, removing the bank layer, and forming a high refractive lens by performing a thermal treatment on the preliminary high refractive lens.

### CROSS-REFERENCE TO RELATED APPLICATION

This application claims priority from to and benefits of Korean Patent Application No. 10-2024-0107085 under 35 U.S.C. § 119, filed on Aug. 9, 2024, in the Korean Intellectual Property Office, the entire contents of which are incorporated herein by reference.

### BACKGROUND

### 1. Technical Field

One or more embodiments relate to a method of manufacturing a display apparatus, and more particularly, to a method of manufacturing a display apparatus including a high refractive lens.

### 2. Description of the Related Art

In general, a display apparatus includes display elements and thin-film transistors formed on a substrate and operates by allowing the display elements to emit light. For example, each of the display elements may include an emission layer between a pixel electrode and an opposite electrode. In order to control a path of light emitted from the emission layer of the display element, a high refractive lens and a low refractive lens, which covers the high refractive lens, are disposed on the display element. The high refractive lens is formed by discharging a material for forming a high refractive lens onto the display element through an inkjet printing process.

### SUMMARY

However, this method of manufacturing a display apparatus has a drawback in that the display quality of the display apparatus may be degraded because the high refractive lens does not have a height sufficient to adjust a path of light emitted from the emission layer of the display element.

One or more embodiments include a method of manufacturing a display apparatus with improved display quality by using a high refractive lens having a sufficient height to control a path of light emitted from an emission layer of a display element, thereby improving the display quality. However, this objective is only an example, and the scope of the disclosure is not limited thereby.

However, embodiments are not limited to those set forth herein. The above and other embodiments will become more apparent to one of ordinary skill in the art to which the disclosure pertains by referencing the detailed description of the disclosure given below.

According to one or more embodiments, a method of manufacturing a display apparatus includes providing a substrate on which a display element is disposed, forming a bank layer on the substrate, the bank layer including an opening overlapping the display element, forming a preliminary high refractive lens by coating the display element with a material for forming a high refractive lens and irradiating the material for forming the high refractive lens with ultraviolet rays, removing the bank layer, and forming the high refractive lens by performing a thermal treatment on the preliminary high refractive lens.

The forming of the preliminary high refractive lens may include coating the display element with the material for forming the high refractive lens so that the material for forming the high refractive lens fills in the opening and covers an upper surface of the bank layer adjacent to the opening.

The forming of the preliminary high refractive lens may include forming the preliminary high refractive lens so that a portion of the bank layer is disposed between a portion of the preliminary high refractive lens and the display element.

The removing of the bank layer may include removing a portion of the bank layer disposed between a portion of the preliminary high refractive lens and the display element.

The forming of the high refractive lens may include performing a thermal treatment on the preliminary high refractive lens so that at least a portion of the preliminary high refractive lens moves toward the substrate.

A height of the high refractive lens may be less than a height of the preliminary high refractive lens.

A thickness of the bank layer may be in a range of about 10 μm to about 50 μm.

The performing of the high refractive lens may include heating the preliminary high refractive lens at a temperature of about 70° C. to about 140° C. for a time of about 80 minutes to about 150 minutes.

An upper surface of the bank layer may be substantially parallel to an upper surface of the substrate.

The bank layer may include a protrusion protruding toward an opposite side of the substrate.

According to one or more embodiments, a method of manufacturing a display apparatus includes providing a substrate on which a plurality of display elements are disposed, forming a bank layer on the substrate, the bank layer including an opening overlapping the plurality of display elements and extending in a direction, forming a preliminary high refractive lens by coating the plurality of display elements with a material for forming a high refractive lens and irradiating the material for forming the high refractive lens with ultraviolet rays, removing the bank layer, and forming the high refractive lens by performing a thermal treatment on the preliminary high refractive lens.

The forming of the preliminary high refractive lens may include coating the plurality of display elements with the material for forming the high refractive lens so that the material for forming the high refractive lens fills in the opening and covers an upper surface of the bank layer adjacent to the opening.

The forming of the preliminary high refractive lens may include forming the preliminary high refractive lens so that a portion of the bank layer is disposed between a portion of the preliminary high refractive lens and the plurality of display elements.

The removing of the bank layer may include removing a portion of the bank layer disposed between a portion of the preliminary high refractive lens and the plurality of display elements.

The forming of the high refractive lens may include performing a thermal treatment on the preliminary high refractive lens so that at least a portion of the preliminary high refractive lens moves toward the substrate.

A height of the high refractive lens may be less than a height of the preliminary high refractive lens.

A thickness of the bank layer may be in a range of about 10 μm to about 50 μm.

The performing of the high refractive lens may include heating the preliminary high refractive lens at a temperature of about 70° C. to about 140° C. for a time of about 80 minutes to about 150 minutes.

An upper surface of the bank layer may be substantially parallel to an upper surface of the substrate.

The bank layer may include a protrusion protruding toward an opposite side of the substrate.

An electronic device may include the display apparatus manufactured by the method.

The electronic device may be at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall with multiple displays tiled together, a theater screen, a stadium screen, a phototherapy device, or a signboard.

Other aspects, features and advantages other than those described above will become apparent from the following detailed description, claims and drawings for working the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view schematically illustrating a display apparatus according to an embodiment;

FIG. 2 is a schematic drawing of an equivalent circuit of a pixel circuit included in the display apparatus according to an embodiment;

FIG. 3 is an enlarged schematic plan view illustrating region A of the display apparatus of FIG. 1;

FIG. 4 is a schematic cross-sectional view illustrating a cross section of the display apparatus of FIG. 3 taken along line B-B′;

FIG. 5 is a schematic plan view illustrating a portion of the display apparatus according to an embodiment;

FIG. 6 is a schematic plan view illustrating a portion of the display apparatus according to an embodiment;

FIG. 7 is an enlarged schematic cross-sectional view illustrating region C of FIG. 4;

FIGS. 8 to 12 are schematic cross-sectional views for describing a method of manufacturing a display apparatus, according to an embodiment;

FIG. 13 is a schematic plan view illustrating a portion of a display apparatus that is manufactured, according to an embodiment;

FIG. 14 is a schematic diagram for describing a method of manufacturing a display apparatus, according to an embodiment;

FIG. 15 is a schematic diagram for describing a method of manufacturing a display apparatus, according to an embodiment;

FIG. 16 is a schematic diagram of an electronic device according to an embodiment; and

FIG. 17 is a schematic diagram of another electronic device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Herein, it will be understood that although terms such as “first” and “second” may be used herein to describe various components, these components should not be limited by these terms and these terms are only used to distinguish one component from another component.

Herein, an expression used in the singular encompasses the expression of the plural, unless it has a clearly different meaning in the context.

Herein, it will be further understood that the terms “comprises” and/or “comprising” used herein specify the presence of stated features or components, but do not preclude the presence or addition of one or more other features or components.

Herein, “A and/or B” may include “A,” “B,” or “A and B.” In addition, “at least one of A and B” represents the case of A, B, or A and B.

Herein, it will be understood that when a component, such as a layer, a film, a region, or a plate, is referred to as being “on” another component, the component can be directly on the other component or intervening components may be present thereon.

Herein, it will be understood that when a layer, region, or component is referred to as being “connected” to another layer, region, or component, it may be “directly connected” to the other layer, region, or component or/and may be “indirectly connected” to the other layer, region, or component with other layer, region, or component therebetween. For example, it will be understood that when a layer, region, or component is referred to as being “electrically connected” to another layer, region, or component, it may be “directly electrically connected” to the other layer, region, or component and/or may be “indirectly electrically connected” to other layer, region, or component with other layer, region, or component interposed therebetween.

Herein, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Herein, when an embodiment may be implemented differently, a certain process order may be performed differently from the described order. For example, two consecutively described processes may be performed substantially at the same time or performed in an order opposite to the described order.

“In a plan view” as used herein refers to a case where a target portion is viewed from above. In other words, “in a plan view” as used herein may refer to “when viewed from a direction perpendicular to a substrate 100.”

Hereinafter, embodiments will be described with reference to the accompanying drawings, wherein like reference numerals refer to like elements throughout and a repeated description thereof is omitted. Sizes of elements in the drawings may be exaggerated or reduced for convenience of explanation. For example, since sizes and thicknesses of elements in the drawings are arbitrarily illustrated for convenience of explanation, the disclosure is not limited thereto.

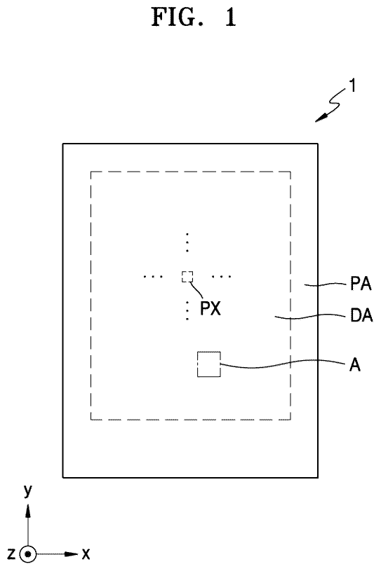

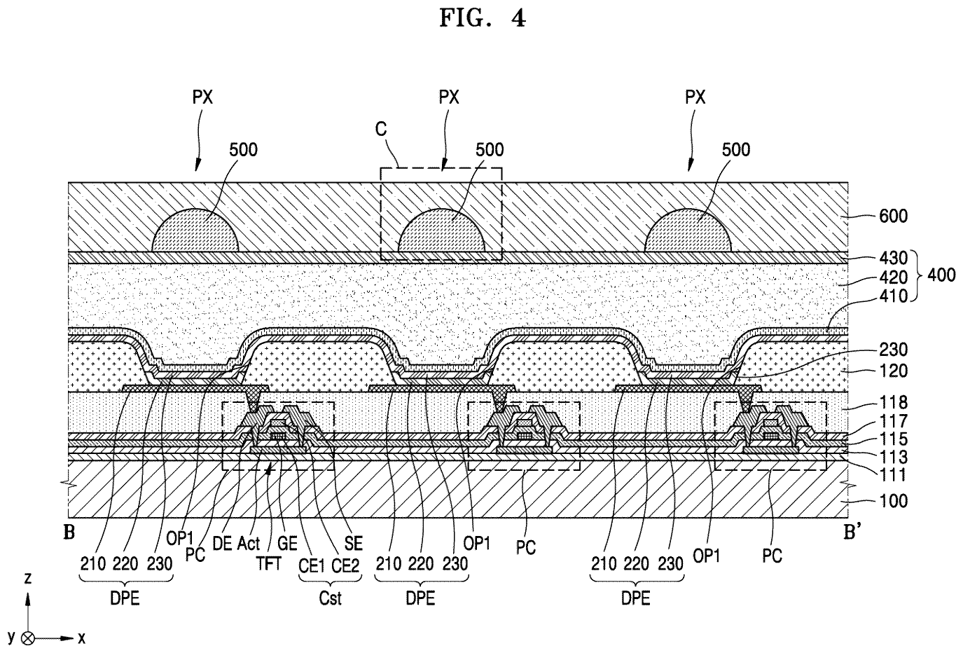

FIG. 1 is a schematic plan view illustrating a display apparatus 1 according to an embodiment. As shown in FIG. 1, the display apparatus 1 may include a display area DA, in which pixels PX are disposed, and a peripheral area PA positioned outside the display area DA. For example, the peripheral area PA may entirely surround the display area DA. For example, a substrate 100 (see FIG. 4) included in the display apparatus 1 may have the display area DA and the peripheral area PA described above.

Each of the pixels PX of the display apparatus 1 may be an area from which light of a certain color is emitted, and the display apparatus 1 may provide an image by using light emitted from the pixels PX. For example, each of the pixels PX may emit one of red light, green light, and blue light.

The display area DA may have a polygonal shape, such as a rectangle as shown in FIG. 1. For example, the display area DA may have a rectangular shape with a horizontal length greater than a vertical length, a rectangular shape with a vertical length greater than a horizontal length, or a square shape. In another example, the display area DA may have various shapes such as an ellipse or a circle.

The peripheral area PA may be a non-display area in which no pixels PX are disposed. A driver or the like for providing electrical signals or power to display elements corresponding to the pixels PX may be disposed in the peripheral area PA. Pads to which various electronic elements or printed circuit boards may be electrically connected may be disposed in the peripheral area PA. Each of the pads may be spaced apart from each other in the peripheral area PA, and may be electrically connected to a printed circuit board or an integrated circuit element.

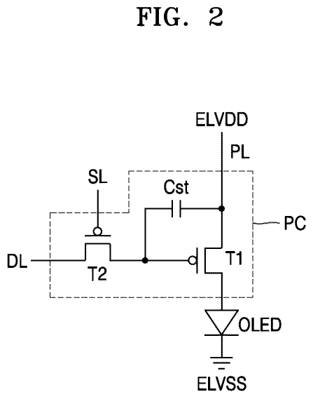

FIG. 2 is a schematic diagram of an equivalent circuit of a pixel circuit PC included in the display apparatus 1 according to an embodiment. The pixel circuit PC may be electrically connected to a display element, and a single display element may correspond to a single pixel PX. In FIG. 2, an organic light-emitting diode OLED is shown as a display element.

The pixel circuit PC may include a first transistor T1, a second transistor T2, and a storage capacitor Cst. The second transistor T2 may be a switching transistor, may be connected to a scan line SL and a data line DL, and may be turned on by a switching signal received via the scan line SL to transmit a data signal received via the data line DL to the first transistor T1. The storage capacitor Cst may have an end portion electrically connected to the second transistor T2 and another end portion electrically connected to a driving voltage line PL, and may store a voltage corresponding to a difference between a voltage received from the second transistor T2 and a driving power voltage ELVDD supplied to the driving voltage line PL.

The first transistor T1 may be a driving transistor, and may be connected to the driving voltage line PL and the storage capacitor Cst to control a magnitude of a driving current flowing from the driving voltage line PL to the organic light-emitting diode OLED in response to a voltage value stored in the storage capacitor Cst. The organic light-emitting diode OLED may emit light with a certain luminance according to the driving current. An opposite electrode of the organic light-emitting diode OLED may receive an electrode power voltage ELVSS.

In FIG. 2, the pixel circuit PC may include two transistors and one storage capacitor. However, one or more embodiments are not limited thereto. For example, the number of transistors or the number of storage capacitors may variously change according to the design of the pixel circuit PC.

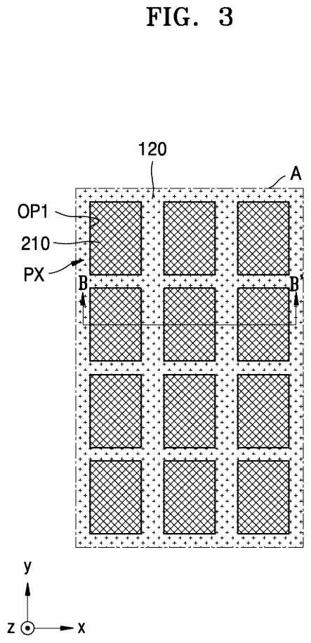

FIG. 3 is an enlarged schematic plan view illustrating region A of the display apparatus 1 of FIG. 1. For descriptive convenience, a plan view on a pixel-defining film 120 is shown in FIG. 3.

As shown in FIG. 3, pixels PX may be disposed in the display area DA. Each of the pixels PX may emit, for example, one of red light, green light, and blue light. Red light may be light in a wavelength band of about 580 nm to about 780 nm, green light may be light in a wavelength band of about 495 nm to about 580 nm, and blue light may be light in a wavelength band of about 400 nm to about 495 nm.

Each of the pixels PX may correspond to a display element such as an organic light-emitting diode. For example, display elements included in the display apparatus 1 may correspond to the respective pixels PX of the display apparatus 1, and each of the display elements may emit one of red light, green light, and blue light. Herein, when it is described that one display element corresponds to one pixel or one pixel corresponds to one display element, it denotes that the pixel is an emission area of the display element.

A laminated structure of a pixel electrode, an emission layer, and an opposite electrode may form one display element, such as an organic light-emitting diode. For example, pixel electrodes 210 may be disposed in the display area DA of the substrate 100. In a plan view, the pixel electrodes 210 may be spaced apart from each other. The pixel-defining film 120 may be disposed on the pixel electrodes 210. The pixel-defining film 120 may include pixel openings OP1. The pixel openings OP1 may expose central portions of the pixel electrodes 210, respectively.

For example, emission layers from which light may be emitted may be positioned in the pixel openings OP1 defined in the pixel-defining film 120. The opposite electrode may be disposed on these emission layers. One pixel opening OP1 defined in the pixel-defining film 120 may define an emission area of one display element. The emission area defined by the pixel opening OP1 may be defined as the pixel PX. In FIG. 3, the pixel openings OP1 may have the same size. However, one or more embodiments are not limited thereto. The pixel openings OP1 may differ in size.

FIG. 4 is a schematic cross-sectional view illustrating a cross section of the display apparatus 1 of FIG. 3, taken along line B-B′. As shown in FIG. 4, the display apparatus 1 according to an embodiment may have the substrate 100.

The substrate 100 may include various materials having flexible or bendable properties. For example, the substrate 100 may include glass, metal, or polymer resin. For example, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may have a multi-layer structure including two layers each including the polymer resin and a barrier layer including an inorganic material (e.g., silicon oxide (SiOₓ), silicon nitride (SiNₓ), and/or silicon oxynitride (SiOxNy)) and positioned between the layers, and various modifications may be made.

A display element DPE and the pixel circuit PC electrically connected to the display element DPE may be disposed on the substrate 100. For example, the pixel circuits PC may be disposed on the substrate 100. The pixel circuits PC may be electrically connected to the display elements DPE, respectively. As the pixel circuits PC are same in structure and the display elements DPE are same in structure, one pixel circuit PC and one display element DPE are mainly described.

The pixel circuit PC may be disposed on the substrate 100. The pixel circuit PC may include transistors TFT and the storage capacitor Cst. For convenience of illustration, FIG. 4 shows one transistor TFT, and this transistor TFT may correspond to the first transistor T1 (see FIG. 2) described above.

A buffer layer 111 including an inorganic material, such as SiOₓ, SiNₓ, and/or SiOₓN_{y}, may be disposed between the transistor TFT and the substrate 100. The buffer layer 111 may increase flatness of an upper surface of the substrate 100, or may prevent or reduce permeation of impurities from the substrate 100 or the like into a semiconductor layer Act of the transistor TFT.

As shown in FIG. 4, the transistor TFT may have the semiconductor layer Act including amorphous silicon, polycrystalline silicon, an organic semiconductor material, or an oxide semiconductor material. For example, the transistor TFT may include a gate electrode GE, a source electrode SE, and/or a drain electrode DE. The gate electrode GE may include various conductive materials and various layered structures. For example, the gate electrode GE may include a molybdenum (Mo) layer and an aluminum (Al) layer. In another example, the gate electrode GE may include a titanium nitride (TiNₓ) layer, an Al layer, and/or a titanium (Ti) layer. The source electrode SE and the drain electrode DE may also include various conductive materials and various layered structures. For example, the source electrode SE and the drain electrode DE may include a Ti layer, an Al layer, and/or a copper (Cu) layer.

In order to ensure insulation between the semiconductor layer Act and the gate electrode GE, a gate insulating layer 113 including an inorganic material, such as SiOₓ, SiNₓ, and/or SiOₓ N_{y}, may be disposed between the semiconductor layer Act and the gate electrode GE. In FIG. 4, the gate insulating layer 113 may have a shape corresponding to an entire surface of the substrate 100, and may have contact holes formed in preset portions. However, one or more embodiments are not limited thereto. For example, the gate insulating layer 113 may be patterned into the same shape as the gate electrode GE.

Further, a first interlayer insulating layer 115 including an inorganic insulating material, such as SiOₓ, SiNₓ, and/or SiOₓN_{y}, may be disposed on the gate electrode GE. The first interlayer insulating layer 115 may have a single-layer structure or a multi-layer structure including the materials described above. An insulating layer including an inorganic insulating material may be formed through chemical vapor deposition (CV) or atomic layer deposition (ALD). This also applies to embodiments and modifications thereof described below.

The storage capacitor Cst may include a first capacitor electrode CE1 and a second capacitor electrode CE2, which overlap each other with the first interlayer insulating layer 115 therebetween. The storage capacitor Cst may overlap the transistor TFT. Regarding this, FIG. 4 shows that the gate electrode GE of the transistor TFT is the first capacitor electrode CE1 of the storage capacitor Cst. However, one or more embodiments are not limited thereto. For example, the storage capacitor Cst may not overlap the transistor TFT. The second capacitor electrode CE2 of the storage capacitor Cst may include a conductive material including molybdenum (Mo), aluminum (AI), copper (Cu), or titanium (Ti), and may have a single-layer structure or a multi-layer structure including these materials.

A second interlayer insulating layer 117 including an inorganic material, such as SiOₓ, SiNₓ, and/or SiOₓN_{y}, may be disposed on the second capacitor electrode CE2 of the storage capacitor Cst. The second interlayer insulating layer 117 may have a single-layer structure or a multi-layer structure including the materials described above.

The source electrode SE and the drain electrode DE may be disposed on the second interlayer insulating layer 117. The source electrode SE and the drain electrode DE may include a material with excellent conductivity. The source electrode SE and the drain electrode DE may include a conductive material including Mo, Al, Cu, or Ti, and may have a single-layer structure or a multi-layer structure including these materials. For example, the source electrode SE and the drain electrode DE may have a multi-layer structure of Ti/Al/Ti.

However, one or more embodiments are not limited thereto. For example, the transistor TFT may include either the source electrode SE or the drain electrode DE. In another example, the transistor TFT may not include both the source electrode SE and the drain electrode DE. For example, one transistor TFT may not have the drain electrode DE, the other transistor TFT connected to this transistor TFT may not have the source electrode SE, and the semiconductor layers Act of these two transistors may be connected to each other. This connection structure may bring about the same effect as when one transistor TFT has the source electrode SE, the other transistor TFT has the drain electrode DE, and the source electrode SE of the one transistor TFT is connected to the drain electrode DE of the other transistor TFT.

As shown in FIG. 4, an organic insulating layer 118 may be disposed to cover the transistor TFT and the storage capacitor Cst. The organic insulating layer 118 may include an organic insulating material. For example, the organic insulating layer 118 may include photoresist, benzocyclobutene (BCB), polyimide, hexamethyldisiloxane (HMDSO), polymethylmethacrylate (PMMA), polystyrene, polymer derivatives having a phenol-based group, acryl-based polymers, imide-based polymers, aryl ether-based polymers, amide-based polymers, fluorine-based polymers, p-xylene-based polymers, vinyl alcohol-based polymers, or any compounds thereof. For example, a third interlayer insulating layer may be further disposed under the organic insulating layer 118. The third interlayer insulating layer may include an inorganic insulating material, such as SiOₓ, SiNₓ, and/or SiOₓN_{y}.

The display element DPE may be disposed on the organic insulating layer 118. For example, the display element DPE may be an organic light-emitting diode. The display element DPE may include a pixel electrode 210, an emission layer 220, and an opposite electrode 230. The opposite electrode 230 may be integrally formed as a single body across the entire surface of the display apparatus 1, and thus may be commonly provided in the display elements DPE.

The pixel electrode 210 may include a light-transmitting conductive layer formed of a light-transmitting conductive oxide, such as indium tin oxide (ITO), indium oxide (In₂O₃), or indium zinc oxide (IZO), and a reflective layer formed of a metal such as Al or silver (Ag). For example, the pixel electrode 210 may have a three-layer structure of ITO/Ag/ITO. As shown in FIG. 4, the pixel electrode 210 may be in contact with either the source electrode SE or the drain electrode DE to be electrically connected to the transistor TFT. For example, the pixel electrode 210 may be in contact with either the source electrode SE or the drain electrode DE through a contact hole defined in the organic insulating layer 118.

The pixel-defining film 120 may be disposed on the organic insulating layer 118. As described above, the pixel-defining film 120 may include the pixel opening OP1. The pixel opening OP1 may expose a central portion of the pixel electrode 210 of the display element DPE. For example, the pixel-defining film 120 may include an opening corresponding to a pixel, e.g., an opening that exposes at least the central portion of the pixel electrode 210, thereby defining the pixel. For example, in FIG. 4, the pixel-defining film 120 may increase a distance between an edge portion of the pixel electrode 210 and the opposite electrode 230 on the pixel electrode 210. Thus, an arc or the like may be prevented from occurring at the edge portion of the pixel electrode 210. The pixel-defining film 120 described above may include an organic material, such as polyimide or HMDSO.

The opposite electrode 230 may be disposed on the pixel electrode 210. The opposite electrode 230 may be integrally formed as a single body across the display elements DPE. Accordingly, the opposite electrode 230 may be disposed on the pixel electrodes 210. The opposite electrode 230 may include a light-transmitting conductive layer formed of ITO, In₂O₃, or IZO, and may also include a semi-transmissive film including a metal such as Al or Ag. For example, the opposite electrode 230 may include a semi-transmissive film including magnesium (Mg) or Ag.

The emission layer 220 capable of emitting light may be disposed between the pixel electrode 210 and the opposite electrode 230. The emission layer 220 may emit one of red light, green light, and blue light. The emission layer 220 may include a polymer or low-molecular weight organic material capable of emitting light of a certain color (red, green, or blue). For example, the emission layer 220 may include a polymer material, for example, based on polyphenylene vinylene (PPV) or polyfluorene. This emission layer 220 may be formed by a screen printing process, an inkjet printing process, or laser induced thermal imaging (LITI) process. However, one or more embodiments are not limited thereto.

In an embodiment, a functional layer may be disposed under and over the emission layer 220. The functional layer may include a hole injection layer (HIL), a hole transport layer (HTL), an electron transport layer (ETL), and/or an electron injection layer (EIL). This functional layer may be integrally formed as a single body across the pixel electrodes 210, or may be patterned to correspond to each of the pixel electrodes 210.

An encapsulation layer 400 may be disposed on the display element DPE. For example, the encapsulation layer 400 may be disposed on the opposite electrode 230. For example, as the display element DPE may be readily damaged by moisture or oxygen from the outside, the encapsulation layer 400 may cover and protect the display element DPE. As shown in FIG. 4, the encapsulation layer 400 may include a first inorganic encapsulation layer 410, an organic encapsulation layer 420, and a second inorganic encapsulation layer 430. For example, the encapsulation layer 400 including the first inorganic encapsulation layer 410, the second inorganic encapsulation layer 430, and the organic encapsulation layer 420 may be disposed on the opposite electrode 230, the organic encapsulation layer 420 being disposed between the first inorganic encapsulation layer 410 and the second inorganic encapsulation layer 430.

The first inorganic encapsulation layer 410 may cover the opposite electrode 230, and may include SiOₓ, SiNₓ, and/or SiOₓN_{y}. However, other layers such as a capping layer may be disposed between the first inorganic encapsulation layer 410 and the opposite electrode 230. As the first inorganic encapsulation layer 410 is formed along a structure thereunder, an upper surface of the first inorganic encapsulation layer 310 may not be flat as shown in FIG. 4. The organic encapsulation layer 420 may cover the first inorganic encapsulation layer 410 so that the upper surface of the first inorganic encapsulation layer 410 may be substantially flat, unlike in the case with first inorganic encapsulation layer 410. The organic encapsulation layer 420 may include one or more materials selected from the group consisting of polyethylene terephthalate, polyethylene naphthalate, polycarbonate, polyimide, polyethylene sulfonate, polyoxymethylene, polyarylate, and HMDSO. The second inorganic encapsulation layer 430 may cover the organic encapsulation layer 420, and may include SiOₓ, SiNₓ, and/or SiOₓN_{y}.

As the encapsulation layer 400 includes the first inorganic encapsulation layer 410, the organic encapsulation layer 420, and the second inorganic encapsulation layer 430, in case that cracks occur in the encapsulation layer 400 through this multi-layer structure, the cracks may be prevented from connecting between the first inorganic encapsulation layer 410 and the organic encapsulation layer 420 or between the organic encapsulation layer 420 and the second inorganic encapsulation layer 430. Through this, the formation of a passage through which moisture or oxygen from the outside permeates into the display apparatus 1 may be prevented or reduced.

For example, a high refractive lens 500 may be disposed on the display element DPE, and a low refractive layer 600 may cover the high refractive lens 500. The high refractive lens 500 and the low refractive layer 600 may adjust a path of light emitted from the emission layer 220 of the display element DPE and may function as a light-collecting lens. The high refractive lens 500 and the low refractive layer 600 may change a path of light traveling in a direction not parallel to an axis (z-axis) perpendicular to the substrate 100 within light emitted from the emission layer 220 of the display element DPE, to guide the light to travel in a direction (+z direction) substantially parallel to the substrate 100.

For example, the high refractive lens 500 may be disposed on the encapsulation layer 400. The high refractive lens 500 may be disposed on the encapsulation layer 400 to overlap the display element DPE. The high refractive lens 500 may be disposed on the encapsulation layer 400 to overlap the pixel opening OP1. For example, the high refractive lens 500 may be disposed on the encapsulation layer 400 to overlap a portion of the pixel electrode 210 exposed through the pixel opening OP1. The low refractive layer 600 may be disposed to cover the high refractive lens 500. For example, the low refractive layer 600 may cover the entire surface on the substrate 100, and the upper surface of the low refractive layer 600 may be substantially flat.

The high refractive lens 500 may include acryl-based resin (e.g., PMMA, polyacrylic acid, or the like), ethylhexyl acrylate, pentafluoropropyl acrylate, polyethylene glycol dimethacrylate, or ethylene glycol dimethacrylate. The high refractive lens 500 may further include a heat-curing agent, such as epoxy, and/or a photo-curing agent. The high refractive lens 500 may have a refractive index higher than a refractive index of the low refractive layer 600. For example, the refractive index of the high refractive lens 500 may be about 1.5 or more, e.g., about 1.5 to about 1.8. For example, the high refractive lens 500 may include an acryl-based organic material having a refractive index of about 1.6. In another example, the high refractive lens 500 may include an acryl-based organic material having a refractive index of about 1.65.

The low refractive layer 600 may include acryl-based resin (e.g., PMMA, polyacrylic acid, or the like), ethylhexyl acrylate, pentafluoropropyl acrylate, polyethylene glycol dimethacrylate, or ethylene glycol dimethacrylate. The low refractive layer 600 may have a refractive index lower than a refractive index of the high refractive lens 500. For example, the refractive index of the low refractive layer 600 may be about 1.2 or more, e.g., about 1.2 to about 1.5.

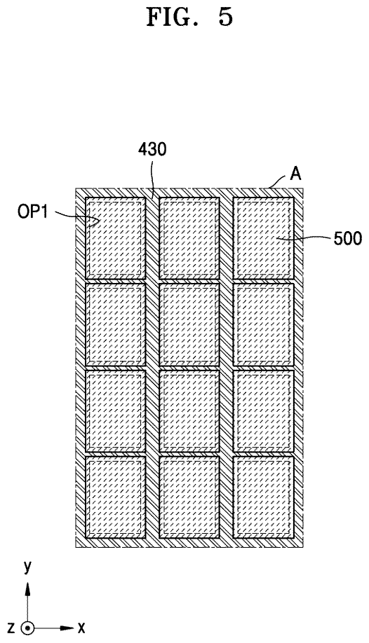

FIG. 5 is a schematic plan view illustrating a portion of the display apparatus 1 according to an embodiment. For example, for descriptive convenience, FIG. 5 shows a plan view on the second inorganic encapsulation layer 430. However, for convenience of description, the high refractive lens 500 disposed on the second inorganic encapsulation layer 430 and the pixel opening OP1 disposed under the second inorganic encapsulation layer 430 are shown together.

As shown in FIG. 5, the high refractive lens 500 may have a shape identical or similar to a shape of the pixel opening OP1. For example, the high refractive lens 500 may be provided in plurality. The high refractive lenses 500 may have shapes identical or similar to shapes of the pixel openings OP1, respectively. Each of the high refractive lenses 500 may be spaced apart from each other. For example, the high refractive lens 500 may be patterned into a shape identical or similar to the shape of the pixel opening OP1. For example, each of the high refractive lenses 500 may be patterned for each display element DPE, and may be individually provided. However, one or more embodiments are not limited thereto.

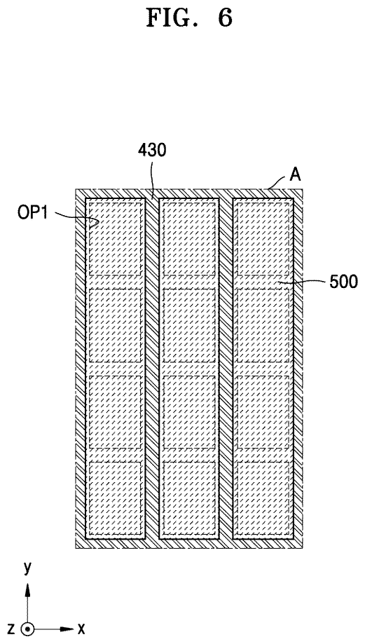

For example, as shown in FIG. 6, which is a plan view illustrating a portion of the display apparatus 1 according to an embodiment, each of the high refractive lenses 500 may extend in a direction. For example, one high refractive lens 500 may overlap the pixel openings OP1. For example, one high refractive lens 500 may be disposed on the display elements DPE. For example, each of the high refractive lenses 500 may be formed across the display elements DPE. Similar to FIG. 5, FIG. 6 also shows a plan view on the second inorganic encapsulation layer 430. For convenience of description, the high refractive lens 500 disposed on the second inorganic encapsulation layer 430 and the pixel opening OP1 disposed under the second inorganic encapsulation layer 430 are shown together.

Although, for descriptive convenience, FIGS. 5 and 6 show that the high refractive lens 500 in a plan view is greater in size than the pixel opening OP1 in a plan view, one or more embodiments are not limited thereto. For example, in case that each of the high refractive lenses 500 is patterned for each display element DPE and is individually provided, as shown in FIG. 5, the high refractive lens 500 in a plan view and the pixel opening OP1 in a plan view may have an equal size. In another example, in case that each of the high refractive lenses 500 is patterned for each display element DPE and is individually provided, as shown in FIG. 5, the high refractive lens 500 in a plan view may be slightly less in size than the pixel opening OP1 in a plan view. In case that each of the high refractive lenses 500 extends in a direction, as shown in FIG. 6, a length of the high refractive lens 500 in a direction (e.g., x-axis direction) intersecting a direction (e.g., y-axis direction) in which each of the high refractive lenses 500 extends may be less than a length of the pixel opening OP1 in this direction.

In an embodiment, a cross section of the high refractive lens 500 may have a semicircular shape. For example, as shown in FIGS. 5 and 6, a shape of the pixel opening OP1 in a plan view may include two short sides and two long sides. The two short sides described above may face each other and extend in a first direction (e.g., x-axis direction), and the two long sides described above may be disposed between the two short sides to face each other and extend in a second direction (e.g., y-axis direction). For example, a height of the high refractive lens 500 may be about ½ of a length of the high refractive lens 500 in the first direction (e.g., x-axis direction).

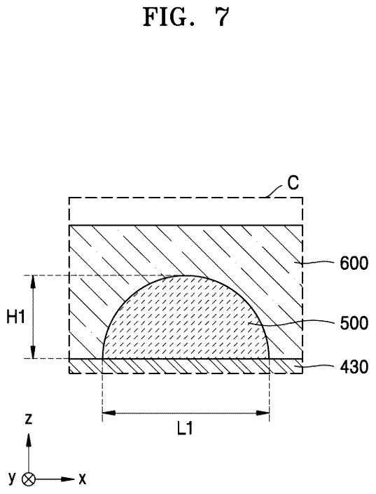

For example, as shown in FIG. 7, which is an enlarged cross-sectional view illustrating region C of FIG. 4, a length of the high refractive lens 500 in a direction in which the short sides of the pixel opening OP1 extend may be a first length L1, and a height of the high refractive lens 500 may be a first height H1. The height of the high refractive lens 500 may be a length of the high refractive lens 500 in a thickness direction (e.g., z-axis direction) of the display apparatus 1. The first height H1 may be about ½ of the first length L1. Accordingly, a cross section of the high refractive lens 500 may have a semicircular shape. In order for the high refractive lens 500 to have an excellent light-collecting effect, the high refractive lens 500 may have a height sufficient to adjust the path of light emitted from the emission layer 220 of the display element DPE. For example, the first height H1 of the high refractive lens 500 may be about ½ of the first length L1 of the high refractive lens 500.

Although FIGS. 5 and 6 show that a shape of the pixel opening OP1 in a plan view has a sharp portion. However, one or more embodiments are not limited thereto. For example, corners, which are formed where one of the two short sides is in contact with one of the two long sides, may have a round shape.

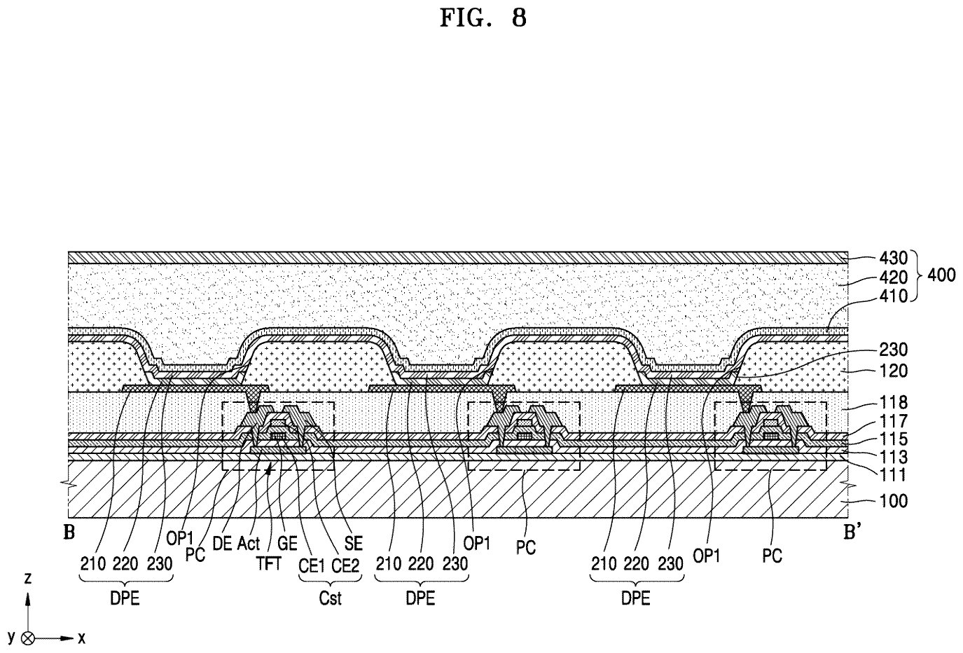

FIGS. 8 to 12 are schematic cross-sectional views for describing a method of manufacturing a display apparatus, according to an embodiment. FIGS. 8 to 12 are schematic cross-sectional views illustrating a process of forming the high refractive lens 500 of the display apparatus 1 of FIG. 4. In FIGS. 8 to 12, the same reference symbols as those of FIG. 4 denote the same member, and redundant descriptions thereof are omitted for descriptive convenience.

As shown in FIG. 8, the substrate 100 may be provided. In the provision of the substrate 100, the display element DPE and the pixel circuit PC electrically connected to the display element DPE may be formed on the substrate 100. The display element DPE described above may be covered by the encapsulation layer 400. For example, the substrate 100 including the display element DPE may be provided. For example, the substrate 100 including the display elements DPE may be provided.

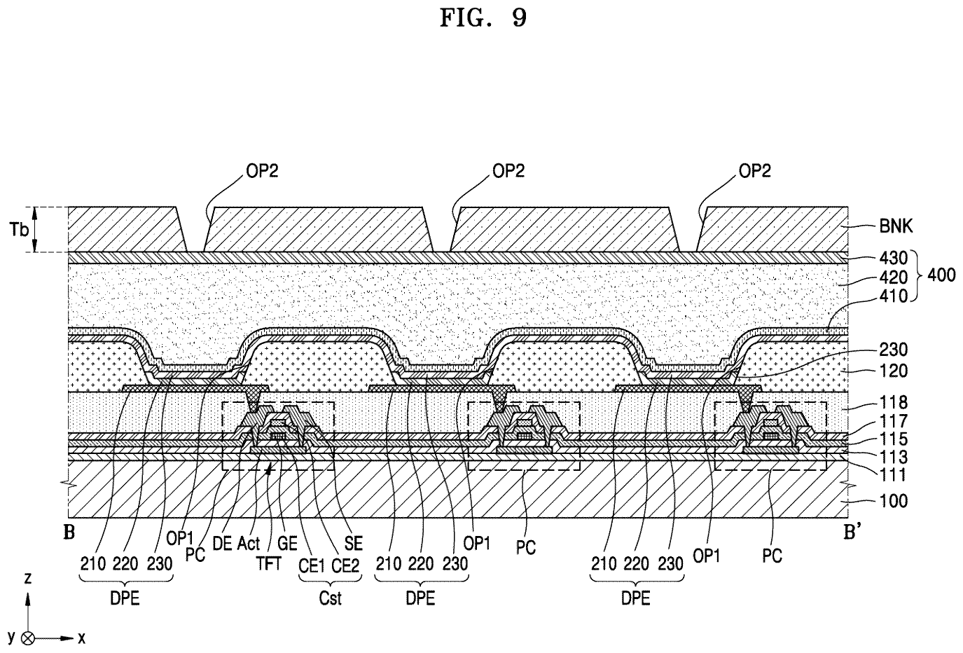

As shown in FIG. 9, a bank layer BNK may be formed on the substrate 100. The bank layer BNK may include a bank opening OP2. The bank opening OP2 may overlap the display element DPE. For example, the bank opening OP2 may overlap the pixel electrode 210. In another example, the bank opening OP2 may overlap the pixel opening OP1.

For example, the bank opening OP2 may overlap a central portion of the display element DPE. The central portion of the display element DPE as used herein refers to a portion of the display element DPE corresponding to a central portion of a portion of the pixel electrode 210 exposed through the pixel opening OP1. For example, a portion of the pixel electrode 210 of the display element DPE may be exposed through the pixel opening OP1. For example, the pixel-defining film 120 may not be disposed on the portion of the pixel electrode 210 exposed through the pixel opening OP1, but the pixel-defining film 120 may be disposed on another portion of the pixel electrode 210 not exposed through the pixel opening OP1. For example, the bank opening OP2 may overlap the central portion of this portion of the pixel electrode 210 exposed through the pixel opening OP1.

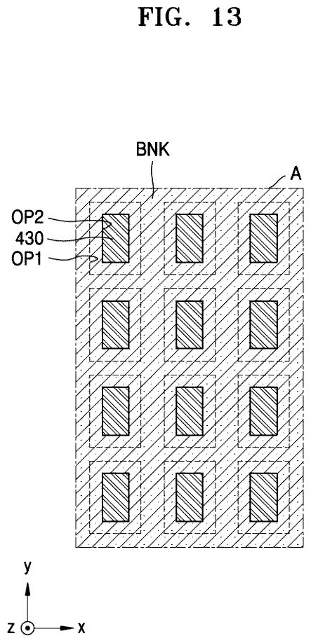

In an embodiment, the bank opening OP2 may overlap the pixel opening OP1 having a size of the bank opening OP2 being less than a size of the pixel opening OP1. For example, as shown in FIG. 13, which is a schematic plan view illustrating a portion of a display apparatus that is manufactured, according to an embodiment, a length of the bank opening OP2 in the first direction (e.g., x-axis direction) may be less than a length of the pixel opening OP1 in the first direction (e.g., x-axis direction), and a length of the bank opening OP2 in the second direction (e.g., y-axis direction) may be less than a length of the pixel opening OP1 in the second direction (e.g., y-axis direction). For descriptive convenience, a plan view on the bank layer BNK is shown in FIG. 13. However, for convenience of description, the pixel opening OP1 disposed under the bank layer BNK is also shown.

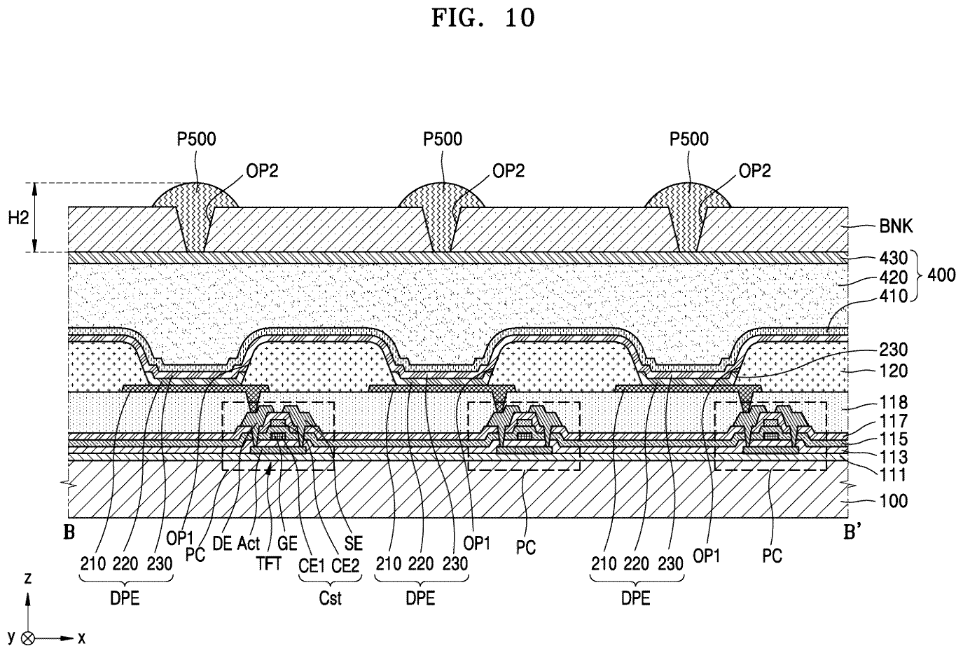

The bank layer BNK may include a lyophobic material. Accordingly, a material for forming a high refractive lens, applied onto the bank layer BNK, may not spread widely, and thus a cross section of a preliminary high refractive lens P500 (see FIG. 10) formed on the bank layer BNK may have a shape similar to a semicircle. For example, the bank layer BNK may include an organic material including fluorine. In another example, the bank layer BNK may include at least one of BCB, polyimide (PI), polyamide (PA), acrylic resin, and phenolic resin. However, one or more embodiments are not limited thereto.

For example, a thickness of the bank layer BNK may be a first thickness Tb. The thickness of the bank layer BNK may be a length of the bank layer BNK in a thickness direction (e.g., z-axis direction) of the display apparatus 1. The first thickness Tb may be about 10 μm to about 50 μm. In case that the first thickness Tb is less than about 10 μm, a height of the high refractive lens 500 formed by using this bank layer BNK is small, and thus a light-collecting effect of the high refractive lens 500 may be reduced. In case that the first thickness Tb exceeds about 50 μm, at least a portion of the preliminary high refractive lens P500 may not sufficiently move toward the substrate 100 due to a heat treatment performed after the bank layer BNK is removed, and thus air bubbles may exist within the high refractive lens 500.

As shown in FIG. 10, the preliminary high refractive lens P500 may be formed. The preliminary high refractive lens P500 may be formed by coating a material for forming a high refractive lens onto the display element DPE and irradiating the coated material for forming a high refractive lens with ultraviolet rays.

For example, the material for forming a high refractive lens may be coated onto the display element DPE. For example, the material for forming a high refractive lens may be discharged onto the display element DPE through an inkjet printing process. The coated material for forming a high refractive lens may fill in the bank opening OP2 and cover the upper surface of the bank opening OP2 adjacent to the bank opening OP2. For example, the material for forming a high refractive lens may be coated onto the display element DPE so that the material for forming a high refractive lens may fill in the bank opening OP2 and cover the upper surface of the bank opening OP2 adjacent to the bank opening OP2.

The material for forming a high refractive lens may be a solution prepared by mixing an acryl-based polymer and/or an acryl-based monomer with an organic solvent. The acryl-based polymer may include PMMA, polyacrylic acid, or polyethylene glycol dimethacrylate, and the acryl-based monomer may include ethylhexyl acrylate, pentafloropropyl acrylate, or ethylene glycol dimethacrylate. However, one or more embodiments are not limited thereto.

The organic solvent may be any solvent that is used to dissolve an acryl-based polymer and an acryl-based monomer, but embodiments are not limited thereto. For example, the organic solvent may include at least one of propylene glycol methyl ether acetate (PGMEA), ethyl lactate, 2-methoxyethyl acetate, propylene glycol monomethyl ether, methyl ethyl ketone, methyl isobutyl ketone, and 1-methyl-2-pyrrolidinone.

For example, the material for forming a high refractive lens may further include a photo-curing agent. The photo-curing agent may be any solvent that is used to photocure an acryl-based polymer and an acryl-based monomer, but embodiments are not limited thereto. For example, the material for forming a high refractive lens may be a solution in which an acryl-based polymer and/or an acryl-based monomer and the photo-curing agent are dissolved in an organic solvent. Viscosity of the material for forming a high refractive lens may be about 14 cp to about 19 cp, and surface tension of the material for forming a high refractive lens may be about 22 dyne/cm to about 30 dyne/cm. For example, the viscosity of the material for forming a high refractive lens may be 18.4 cp, and the surface tension of the material for forming a high refractive lens may be 25 dyne/cm. In another example, the viscosity of the material for forming a high refractive lens may be 15 cp, and the surface tension of the material for forming a high refractive lens may be 28 dyne/cm.

The coated material for forming a high refractive lens may be irradiated with ultraviolet rays. Accordingly, the coated material for forming a high refractive lens may be photocured, and the preliminary high refractive lens P500 may be formed. For example, the preliminary high refractive lens P500 may be obtained by photo-curing the coated material for forming a high refractive lens. For example, the coated material for forming a high refractive lens may be irradiated with ultraviolet rays having a light amount of about 1,000 mJ/cm² to about 3,000 mJ/cm². For example, the coated material for forming a high refractive lens may be irradiated with ultraviolet rays having a light amount of 2,000 mJ/cm². Ultraviolet rays having a wavelength of about 300 nm to about 400 nm may be used for photo-curing. A light-emitting diode (LED) or metal halide may be used as an ultraviolet ray source. For example, the coated material for forming a high refractive lens may be irradiated with ultraviolet rays, and the preliminary high refractive lens P500 may be formed.

The formed preliminary high refractive lens P500 may fill in the bank opening OP2 and cover the upper surface of the bank opening OP2 adjacent to the bank opening OP2. For example, a portion of the bank layer BNK may be disposed between a portion of the preliminary high refractive lens P500 and the display element DPE. For example, a portion of the bank layer BNK may be disposed between a portion of the preliminary high refractive lens P500 and the second inorganic encapsulation layer 430. A portion of the bank layer BNK may not be disposed between another portion of the preliminary high refractive lens P500 and the display element DPE. For example, the other portion of the high refractive lens 500 may be in contact with (e.g., in direct contact with) the second inorganic encapsulation layer 430.

For example, a height of the preliminary high refractive lens P500 may be a second height H2. The height of the preliminary high refractive lens P500 may be a length of the preliminary high refractive lens P500 in a thickness direction (e.g., z-axis direction) of the display apparatus 1. As described above, as the preliminary high refractive lens P500 fills in the bank opening OP2 and covers the upper surface of the bank layer BNK adjacent to the bank opening OP2, the height of the preliminary high refractive lens P500 may be measured based on a layer (e.g., the second inorganic encapsulation layer 430) disposed under the bank layer BNK to be in contact with (e.g., in direct contact with) the bank layer BNK.

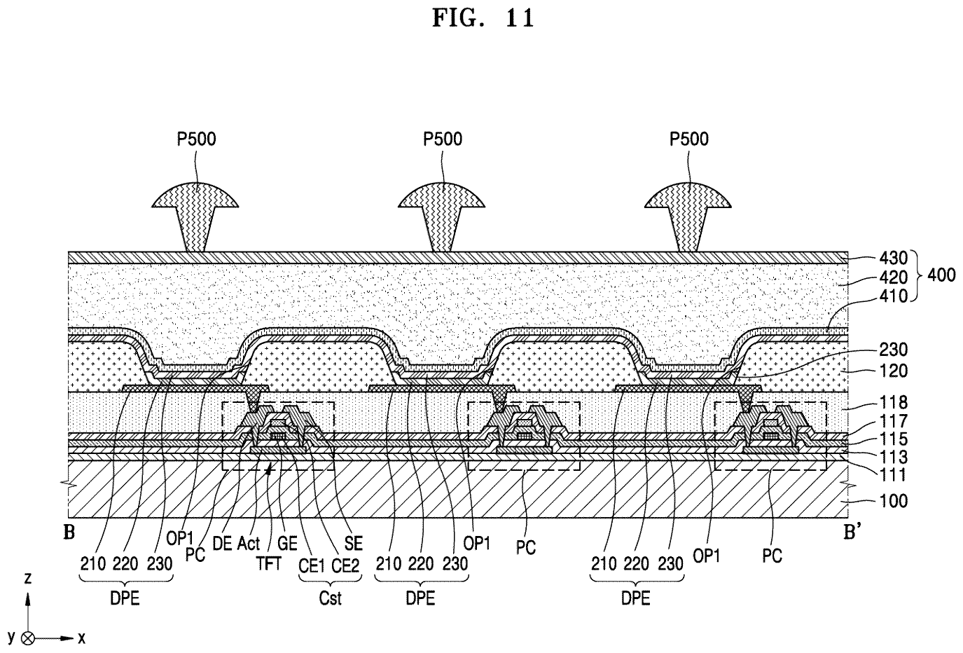

As shown in FIG. 11, the bank layer BNK may be removed. Accordingly, a portion of the bank layer BNK between a portion of the preliminary high refractive lens P500 and the display element DPE may also be removed. For example, the bank layer BNK may be removed by a strip process or a wet etch process. In case that the bank layer BNK is removed, the preliminary high refractive lens P500 may not be removed. For example, without removing the preliminary high refractive lens P500, the bank layer BNK may be selectively removed by a strip process or a wet etch process. This selective removal (or selective etching) may be performed by allowing the preliminary high refractive lens P500 to be less cured than the bank layer BNK. In another example, this selective removal may be performed using a solvent that dissolves the bank layer BNK but may not dissolve the preliminary high refractive lens P500 during a strip process or a wet etch process. As this selective removal is well-known, detailed descriptions thereof are omitted for descriptive convenience.

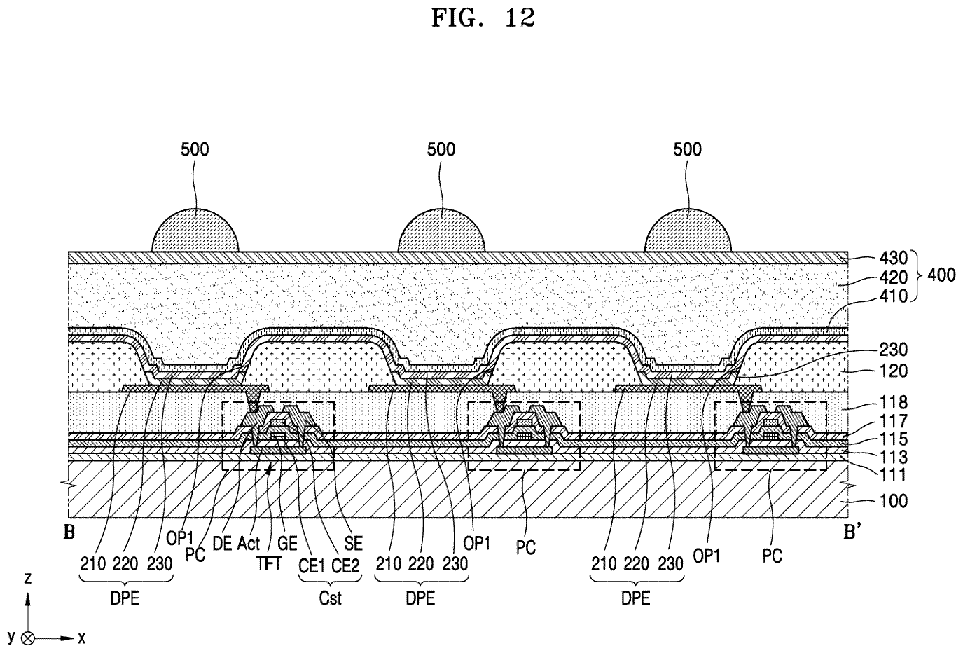

As shown in FIG. 12, a thermal treatment may be performed on the preliminary high refractive lens P500. Accordingly, the high refractive lens 500 may be formed. For example, in case that the preliminary high refractive lens P500 is thermally-treated, the preliminary high refractive lens P500 may have fluidity. For example, the preliminary high refractive lens P500 may be reflowed. At least a portion of this preliminary high refractive lens P500 may move toward the substrate 100. For example, as described above, before the bank layer BNK is removed, a portion of the bank layer BNK may be between a portion of the preliminary high refractive lens P500 and the second inorganic encapsulation layer 430, the portion of the preliminary high refractive lens P500 may be spaced apart from the second inorganic encapsulation layer 430. However, this portion of the preliminary high refractive lens P500 may move toward the substrate 100 by the thermal treatment performed after the bank layer BNK is removed, so as to be in contact with (e.g., in direct contact with) the second inorganic encapsulation layer 430. Accordingly, the first height H1, which is the height of the high refractive lens 500, may be less than the second height H2 of the preliminary high refractive lens P500.

For example, the preliminary high refractive lens P500 may be heated at a temperature of about 70° C. to about 140° C. for a time of about 80 minutes to about 150 minutes. For example, the preliminary high refractive lens P500 may be heated at a temperature of about 85° C. for about 120 minutes. In another example, the preliminary high refractive lens P500 may be heated at a temperature of about 100° C. for about 120 minutes. In case that the preliminary high refractive lens P500 is heated at a temperature below 70° C., the preliminary high refractive lens P500 cannot have sufficient fluidity to allow at least a portion of the preliminary high refractive lens P500 to move toward the substrate 100. In case that the preliminary high refractive lens P500 is heated at a temperature exceeding about 140° C., excessive heat energy may be applied to the preliminary high refractive lens P500, which causes the formed high refractive lens 500 to deteriorate. In case that the preliminary high refractive lens P500 is heated for less than about 80 minutes, the preliminary high refractive lens P500 cannot have sufficient fluidity to allow at least a portion of the preliminary high refractive lens P500 to move toward the substrate 100. In case that the preliminary high refractive lens P500 is heated for more than about 150 minutes, excessive heat energy may be applied to the preliminary high refractive lens P500, which causes the formed high refractive lens 500 to deteriorate.

For example, the material for forming a high refractive lens may be discharged through an inkjet printing process onto the display element DPE in which the bank layer BNK does not exist. During the inkjet printing process, in order to facilitate discharge of the material for forming a high refractive lens, the viscosity and/or surface tension of the material for forming a high refractive lens is limited to a preset (or selected) range. In case that the viscosity and/or surface tension of the material for forming a high refractive lens is not high, the material for forming a high refractive lens coated onto the display element DPE may spread widely. Accordingly, the height of the high refractive lens 500 may decrease, and the light-collecting effect of the high refractive lens 500 may be reduced.

However, in a manufacturing method according to an embodiment, the material for forming a high refractive lens may be coated onto the display element DPE to fill in the bank opening OP2 defined in the bank layer BNK and cover the upper surface of the bank layer BNK adjacent to the bank opening OP2. For example, the material for forming a high refractive lens may be discharged onto the display element DPE through the inkjet printing process so as to fill in the bank opening OP2 defined in the bank layer BNK and cover the upper surface of the bank layer BNK adjacent to the bank opening OP2. Accordingly, the high refractive lens 500 of the display apparatus 1 manufactured according to an embodiment may have a height sufficient to control a path of light emitted from the emission layer 220 of the display apparatus 1, and the light-collecting effect of the high refractive lens 500 is not reduced.

In FIG. 13, each of the bank openings OP2 may overlap a corresponding one of the pixel openings OP1. However, one or more embodiments are not limited thereto. For example, one bank opening OP2 may overlap the pixel openings OP1.

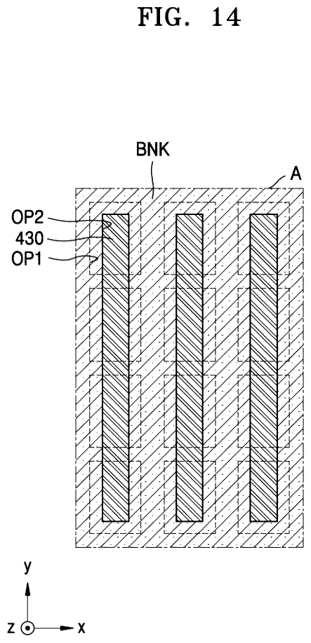

FIG. 14 is a schematic diagram for describing a method of manufacturing a display apparatus, according to an embodiment. FIG. 14 is a schematic plan view illustrating a portion of a display apparatus that is manufactured according to an embodiment, and FIG. 14 shows a plan view on the bank layer BNK. However, for convenience of description, the pixel opening OP1 disposed under the bank layer BNK is also shown. As the method of manufacturing a display apparatus according to an embodiment corresponds to a modification of the method of manufacturing a display apparatus described above with reference to FIGS. 8 to 13, differences from the method of manufacturing a display apparatus described above with reference to FIGS. 8 to 13 are mainly described below. For example, FIG. 14 corresponds to FIG. 13. In FIG. 14, the same reference characters as those of FIGS. 8 to 13 denote the same members, and redundant descriptions thereof are omitted for descriptive convenience.

Also in the method of manufacturing a display apparatus according to an embodiment, the preliminary high refractive lens P500 may be formed by providing the substrate 100 including the display element DPE, forming the bank layer BNK on the substrate 100, coating a material for forming a high refractive lens onto the display element DPE, and irradiating the material for forming a high refractive lens with ultraviolet rays. For example, also in a method of manufacturing a display apparatus, according to an embodiment, the high refractive lens 500 may be formed by removing the bank layer BNK and performing a thermal treatment on the preliminary high refractive lens P500. These procedures are identical to those of the method of manufacturing a display apparatus described above with reference to FIGS. 8 to 13, and thus redundant descriptions thereof are omitted for descriptive convenience.

However, in the method of manufacturing a display apparatus according to an embodiment, one bank opening OP2 may overlap the pixel openings OP1, as shown in FIG. 14. For example, the bank opening OP2 may extend in a direction. For example, the bank opening OP2 may extend in the second direction (e.g., the y-axis direction). As shown in FIG. 14, a length of the bank opening OP2 in the first direction (e.g., x-axis direction) may be less than a length of the pixel opening OP1 in the first direction (e.g., x-axis direction), but a length of the bank opening OP2 in the second direction (e.g., y-axis direction) may be greater than a length of the pixel opening OP1 in the second direction (e.g., y-axis direction).

Accordingly, a single bank opening OP2 may overlap the pixel openings OP1. For example, the single bank opening OP2 may overlap the display elements DPE. For example, the bank opening OP2 may overlap central portions of the display elements DPE. In case that the high refractive lens 500 is formed using the bank opening OP2 described above, the formed high refractive lens 500 may have a height sufficient to control a path of light emitted from the emission layer 220 of the display element DPE, and the light-collecting effect of the high refractive lens 500 may not be reduced.

In FIGS. 8 to 12, the upper surface of the bank layer BNK may be parallel to the upper surface of the substrate 100. However, one or more embodiments are not limited thereto. For example, the upper surface of the bank layer BNK may protrude toward the substrate 100.

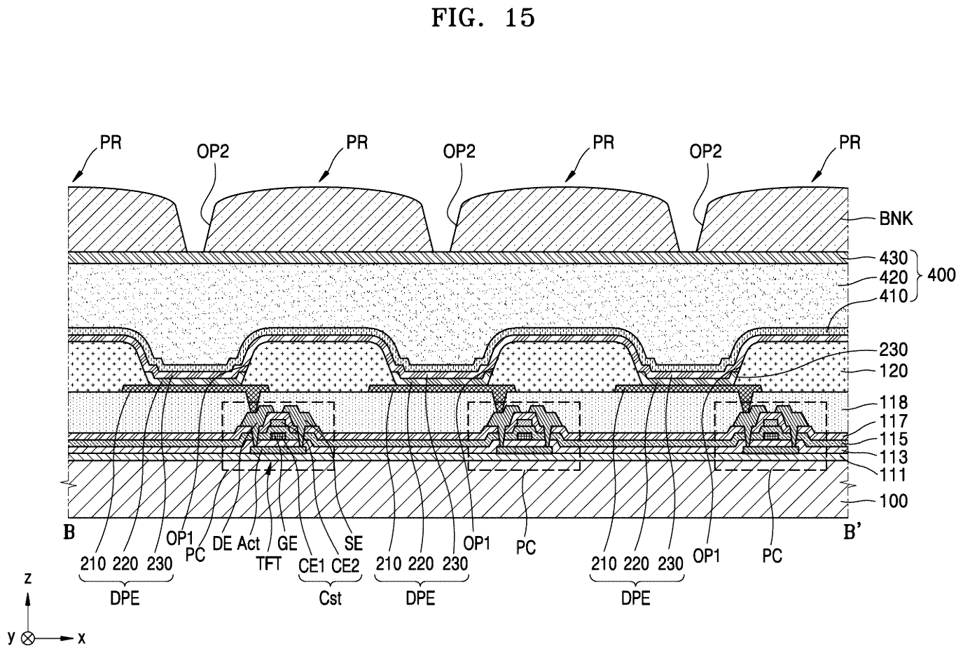

FIG. 15 is a schematic diagram for describing a method of manufacturing a display apparatus, according to an embodiment. FIG. 15 is a cross-sectional view schematically illustrating a portion of a display apparatus that is manufactured according to an embodiment. As the method of manufacturing a display apparatus according to an embodiment corresponds to a modification of the method of manufacturing a display apparatus described above with reference to FIGS. 8 to 13, differences from the method of manufacturing a display apparatus described above with reference to FIGS. 8 to 13 are mainly described below. FIG. 15 corresponds to FIG. 9. In FIG. 15, the same reference characters as those of FIGS. 8 to 13 denote the same members, and redundant descriptions thereof are omitted for descriptive convenience.

Also in the method of manufacturing a display apparatus according to an embodiment, the preliminary high refractive lens P500 may be formed by providing the substrate 100 including the display element DPE, forming the bank layer BNK on the substrate 100, coating a material for forming a high refractive lens onto the display element DPE, and irradiating the material for forming a high refractive lens with ultraviolet rays. For example, also in a method of manufacturing a display apparatus, according to an embodiment, the high refractive lens 500 may be formed by removing the bank layer BNK and performing a thermal treatment on the preliminary high refractive lens P500. These procedures are identical to those of the method of manufacturing a display apparatus described above with reference to FIGS. 8 to 13, and thus redundant descriptions thereof are omitted for descriptive convenience.

However, in the method of manufacturing a display apparatus according to an embodiment, the bank layer BNK may include a protrusion PR toward the opposite direction of the substrate 100, as shown in FIG. 15. Accordingly, the upper surface of the bank layer BNK may protrude toward the substrate 100. This bank layer BNK may also include the bank opening OP2. The bank opening OP2 may overlap a central portion of the display element DPE. In case that the high refractive lens 500 is formed by the bank layer BNK described above, the formed high refractive lens 500 may have a height sufficient to control a path of light emitted from the emission layer 220 of the display element DPE, and the light-collecting effect of the high refractive lens 500 may not be reduced.

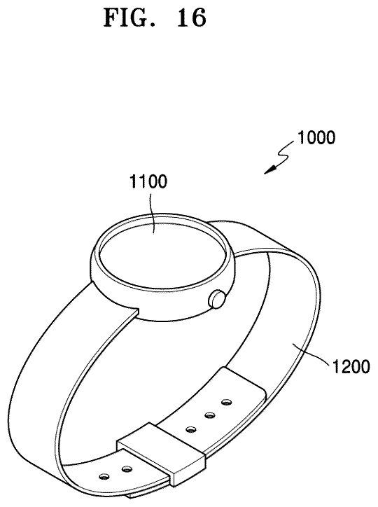

Referring to FIG. 16, the display apparatus may be applied to an electronic device including a smart watch 1000 including a display part 1100 and a strap part 1200.

The smart watch 1000 may be a wearable electronic device. For example, the smart watch 1000 may have a structure in which the strap part 1200 is mounted on a wrist of a user. The electronic device may be applied to the display part 1100, so that image data including time information can be provided to the user.

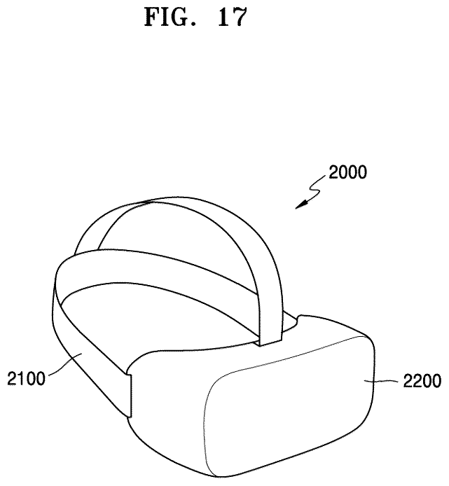

Referring to FIG. 17, the electronic device may include a head mounted display device 2000.

The head mounted display device 2000 may be a wearable electronic device which can be worn on the head of a user. For example, the head mounted display device 2000 may be a wearable device for virtual reality (VR) or mixed reality (MR). The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure.

For example, the electronic device may be at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall with multiple displays tiled together, a theater screen, a stadium screen, a phototherapy device, or a signboard.

According to an embodiment configured as described above, a high refractive lens may have a height sufficient to control the path of light emitted from an emission layer of a display element, so that a method of manufacturing a display apparatus with improved display quality may be implemented. However, the scope of the disclosure is not limited by this effect.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A method of manufacturing a display apparatus, the method comprising:
providing a substrate on which a display element is disposed;
forming a bank layer on the substrate, the bank layer comprising an opening overlapping the display element;
forming a preliminary high refractive lens by coating the display element with a material for forming a high refractive lens and irradiating the material for forming the high refractive lens with ultraviolet rays;
removing the bank layer; and
forming the high refractive lens by performing a thermal treatment on the preliminary high refractive lens.

2. The method of claim 1, wherein the forming of the preliminary high refractive lens comprises coating the display element with the material for forming the high refractive lens so that the material for forming the high refractive lens fills in the opening and covers an upper surface of the bank layer adjacent to the opening.

3. The method of claim 1, wherein the forming of the preliminary high refractive lens comprises forming the preliminary high refractive lens so that a portion of the bank layer is disposed between a portion of the preliminary high refractive lens and the display element.

4. The method of claim 1, wherein the removing of the bank layer comprises removing a portion of the bank layer disposed between a portion of the preliminary high refractive lens and the display element.

5. The method of claim 1, wherein the forming of the high refractive lens comprises performing a thermal treatment on the preliminary high refractive lens so that at least a portion of the preliminary high refractive lens moves toward the substrate.

6. The method of claim 5, wherein a height of the high refractive lens is less than a height of the preliminary high refractive lens.

7. The method of claim 1, wherein a thickness of the bank layer is in a range of about 10 μm to about 50 μm.

8. The method of claim 1, wherein the performing of the high refractive lens comprises heating the preliminary high refractive lens at a temperature of about 70° C. to about 140° C. for a time of about 80 minutes to about 150 minutes.

9. The method of claim 1, wherein an upper surface of the bank layer is substantially parallel to an upper surface of the substrate.

10. The method of claim 1, wherein the bank layer comprises a protrusion protruding toward an opposite side of the substrate.

11. A method of manufacturing a display apparatus, the method comprising:
providing a substrate on which a plurality of display elements are disposed;
forming a bank layer on the substrate, the bank layer comprising an opening overlapping the plurality of display elements and extending in a direction;
forming a preliminary high refractive lens by coating the plurality of display elements with a material for forming a high refractive lens and irradiating the material for forming the high refractive lens with ultraviolet rays;
removing the bank layer; and
forming the high refractive lens by performing a thermal treatment on the preliminary high refractive lens.

12. The method of claim 11, wherein the forming of the preliminary high refractive lens comprises coating the plurality of display elements with the material for forming the high refractive lens so that the material for forming the high refractive lens fills in the opening and covers an upper surface of the bank layer adjacent to the opening.

13. The method of claim 11, wherein the forming of the preliminary high refractive lens comprises forming the preliminary high refractive lens so that a portion of the bank layer is disposed between a portion of the preliminary high refractive lens and the plurality of display elements.

14. The method of claim 11, wherein the removing of the bank layer comprises removing a portion of the bank layer disposed between a portion of the preliminary high refractive lens and the plurality of display elements.

15. The method of claim 11, wherein the forming of the high refractive lens comprises performing a thermal treatment on the preliminary high refractive lens so that at least a portion of the preliminary high refractive lens moves toward the substrate.

16. The display apparatus of claim 15, wherein a height of the high refractive lens is less than a height of the preliminary high refractive lens.

17. The method of claim 11, wherein a thickness of the bank layer is in a range of about 10 μm to about 50 μm.

18. The method of claim 11, wherein the performing of the high refractive lens comprises heating the preliminary high refractive lens at a temperature of about 70° C. to about 140° C. for a time of about 80 minutes to about 150 minutes.

19. An electronic device comprising the display apparatus manufactured by the method of claim 1.

20. The electronic device of claim 19, wherein the electronic device is at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall with multiple displays tiled together, a theater screen, a stadium screen, a phototherapy device, or a signboard.
